(19) United States
(12) Patent Application Publication
(10) Pub. No.: US 2025/0112066 A1
(43) Pub. Date: Apr. 3, 2025

(54) LIQUID PROCESSING APPARATUS, AND MONITORING METHOD

(71) Applicant: Tokyo Electron Limited, Tokyo (JP)

(72) Inventors: Shinichi MIZUSHINO, Koshi City (JP); Shunsuke INTO, Koshi City (JP); Yuichiro KUNUGIMOTO, Koshi City (JP); Akihiro TOYOZAWA, Koshi City (JP); Daisuke ISHIMARU, Koshi City (JP); Yuki MATSUTAKE, Koshi City (JP); Shigeyuki IIDA, Sapporo City (JP); Takafumi HAYAMA, Koshi City (JP)

(73) Assignee: Tokyo Electron Limited, Tokyo (JP)

(21) Appl. No.: 18/899,015

(22) Filed: Sep. 27, 2024

(30) Foreign Application Priority Data
Sep. 29, 2023 (JP) 2023-170415

(51) Int. Cl. H01L 21/67; G02F 1/29; G03B 13/34; G03F 7/16; H01L 21/66; H04N 23/56; H04N 23/60

(52) U.S. Cl. CPC H01L 21/67253; G02F 1/294; G03B 13/34; G03F 7/162; H01L 22/12; H04N 23/56; H04N 23/64

(57) ABSTRACT

A liquid processing apparatus includes multiple stages on each of which a substrate is to be placed; multiple nozzles shared by the multiple stages, and each for supplying a processing liquid to the substrate; a camera shared by the multiple nozzles, and for monitoring states of the multiple nozzles; and an imaging condition changing program module for causing circuitry to change an imaging condition of the camera according to a monitoring condition.

### CROSS-REFERENCE TO RELATED APPLICATION

This application claims the benefit of Japanese Patent Application No. 2023-170415 filed on Sep. 29, 2023, the entire disclosure of which are incorporated herein by reference.

### TECHNICAL FIELD

The various aspects and embodiments described herein pertain generally to a liquid processing apparatus and a monitoring method.

### BACKGROUND

In a manufacture of a semiconductor device, a liquid processing apparatus is equipped with a nozzle that discharges a processing liquid such as resist to a semiconductor wafer (hereinafter, simply referred to as a wafer) to form a resist film on the wafer. For example, Patent Document 1 describes monitoring a discharge state of a photoresist liquid from a processing liquid supply nozzle onto a substrate with a CCD camera to detect abnormality in the discharge state.

Patent Document 1: Japanese Patent Laid-open Publication No. 2003-318079

### SUMMARY

In an exemplary embodiment, a liquid processing apparatus includes multiple stages on each of which a substrate is to be placed; multiple nozzles shared by the multiple stages, and each configured to supply a processing liquid to the substrate; a camera shared by the multiple nozzles, and configured to monitor states of the multiple nozzles; and an imaging condition changing module configured to change an imaging condition of the camera according to a monitoring condition.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a liquid processing apparatus according to an exemplary embodiment;

FIG. 2 is a longitudinal side view illustrating the liquid processing apparatus;

FIG. 3 is a longitudinal side view illustrating the liquid processing apparatus;

FIG. 4 is a plan view illustrating a state in which a thinner nozzle is moved to a discharge position;

FIG. 5 is a plan view illustrating a state in which a resist nozzle is moved to the discharge position;

FIG. 6 is an explanatory diagram schematically illustrating focus adjustment;

FIG. 7 is an explanatory diagram schematically illustrating the focus adjustment;

FIG. 8 shows an image with the thinner nozzle in focus;

FIG. 9 shows an image with the resist nozzle in focus;

FIG. 10 is a flowchart illustrating an operation of the liquid processing apparatus;

FIG. 11 is a graph showing a focus time ratio of a nozzle that is not discharging a processing liquid;

FIG. 12 is a plan view illustrating a liquid processing apparatus according to a first modification example;

FIG. 13 is a plan view illustrating a liquid processing apparatus according to a second modification example; and

FIG. 14 is a plan view illustrating a liquid processing apparatus according to a third modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

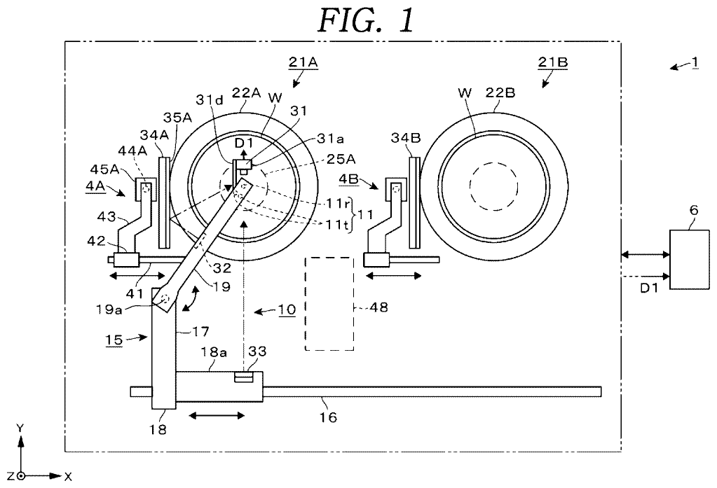

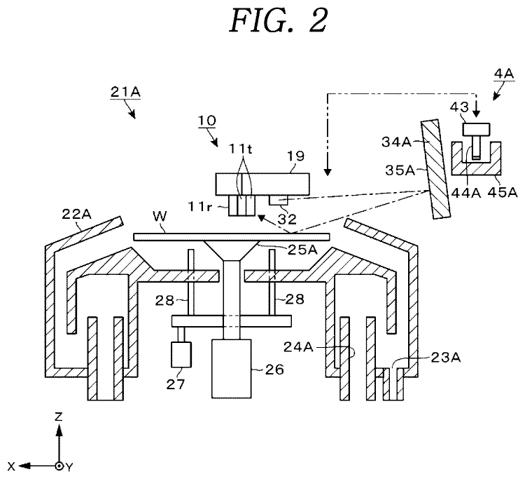

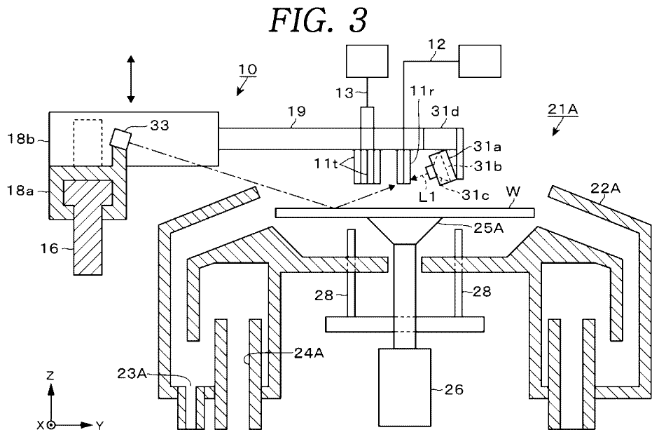

FIG. 1 is a plan view illustrating a resist coating apparatus as an exemplary embodiment of a liquid processing apparatus according to the present disclosure, in which a nozzle 11, specifically a resist nozzle 11r is disposed at a discharge position to described later. In the present exemplary embodiment, description will be made by using an XYZ orthogonal coordinate system. The resist coating apparatus is equipped with processing devices 21A and 21B as places where respective processings are performed on a wafer W. FIG. 2 is a longitudinal side view of the processing device 21A along the Y-axis direction, and FIG. 3 is a longitudinal side view of the processing device 21A along the X-axis direction. Hereinafter, the X-axis direction may also be referred to as transversal direction, and the Y-axis direction may also be referred to as forward--and-backward direction. Also, the side where a processing liquid supply mechanism 10 including the nozzle 11 is disposed may sometimes be referred to as a front side, and the opposite side where the processing devices 21A and 21B are disposed may sometimes be referred to as a rear side.

The resist coating apparatus is equipped with the processing liquid supply mechanism 10 configured to supply thinner and resist as processing liquids to the wafer W in order to form a resist film on the wafer W. The thinner is a processing liquid supplied to the wafer W prior to the supply of the resist to be used in a process (pre-wetting) of improving wettability of a surface of the wafer W for the resist.

The thinner is also used for EBR (Edge Bead Removal), in which the thinner is discharged to a peripheral portion of the wafer W having the resist film formed thereon to annularly remove an unnecessary portion of the resist film. The thinner for this EBR is supplied from EBR mechanisms 4A and 4B provided separately from the processing liquid supply mechanism 10. In this way, in the resist coating apparatus 1, the wafer W is subjected to the pre-wetting, the resist coating, and the EBR in this order in each of the processing devices 21A and 21B.

The processing liquid supply mechanism 10 configured to perform the pre-wetting and the resist coating is shared by the processing devices 21A and 21B. In order to enable a controller 6 (the controller 6 may be implemented within one or more of Application Specific Integrated Circuits (ASICs), Digital Signal Processors (DSPs), Digital Signal Processing Devices (DSPDs), Programmable Logic Devices (PLDs), Field Programmable Gate Arrays (FPGAs), processors, controllers, micro-controllers, microprocessors, other electronic units designed to perform the functions described herein, or a selective combination thereof) to described later to monitor the state of each nozzle 11 constituting this processing liquid supply mechanism 10, the resist coating apparatus is provided with a camera 31 configured to image the nozzle 11, a plurality of illuminators, and a reflecting member 34 (e.g., reflector) configured to reflect lights radiated from some of the plurality of illuminators. The plurality of illuminators and the reflecting member 34 illuminate an imaging area of the camera 31, that is, the nozzle 11 and the vicinity thereof. As will be described later in detail, the radiation of the light from each illuminator to the nozzle 11 is carried out via the surface of the wafer W. In other words, the light emitted from the illuminator is radiated to the nozzle 11 by being reflected on the surface of the wafer W. The reflecting member 34 reflects the light from the illuminator toward the wafer W.

Hereinafter, the processing devices 21A and 21B will be explained. The processing devices 21A and 21B are arranged along the X direction, and the processing devices 21A and 21B may sometimes be generically referred to as a processing device 21. Since the processing devices 21A and 21B have the same configuration, the processing device 21A will be described as a representative.

As shown in FIG. 2, the processing device 21A is equipped with a cup 22A having an open top and configured to accommodate the wafer W in a holding area therein. A reference numeral 23A in FIG. 2 denotes a drain port provided in the cup 22A, and a reference numeral 24A denotes an exhaust port for evacuating the cup 22A during a processing of the wafer W. A spin chuck 25A, which is a stage on which the wafer W is to be placed, is provided inside the cup 22A. The spin chuck 25A is configured to attract a center of a rear surface of the wafer W and hold the wafer W horizontally. A lower portion of the spin chuck 25A is connected to a rotational driver 26. The spin chuck 25A is rotated by the rotational driver 26 around a vertical axis (Z-axis) together with the wafer W. Three pins (only two are shown in FIG. 2) configured to be moved up and down by an elevating mechanism 27 are provided inside the cup 22 to deliver the wafer W between a transfer mechanism (not shown) configured to transfer the wafer W and the spin chuck 25A.

The processing device 21A is provided with a reflecting member 34A and an EBR mechanism 4A configured to perform EBR. The EBR mechanism 4A is disposed in an area on the left of the cup 22A. The EBR mechanism 4A includes a guide 41, a mover 42, an arm 43, a peripheral nozzle 44A, and a cup-shaped standby section 45A. The mover 42 moves linearly in a left-and-right direction (X-axis direction) along the guide 41 on the front side of the cup 22A. Further, the arm 43 configured to be movable up and down extends rearwards from the mover 42, and the peripheral nozzle 44A is provided at a rear end of the arm 43.

The peripheral nozzle 44A is connected to a non-illustrated thinner supply mechanism via a pipeline. The thinner supply mechanism supplies thinner to the peripheral nozzle 44A that has been moved to a predetermined discharge position within the cup 22A, so that the thinner is discharged downwards. The thinner is discharged onto a peripheral portion of the wafer W being rotated by the spin chuck 25A, so that the EBR is performed.

The standby section 45A is provided outside the cup 22A, and is located on the left of the cup 22A with respect to the center of the cup 22A in the forward-and-backward direction. The peripheral nozzle 44A is moved by the mover 42 between a standby position inside the standby section 45A and the discharge position. When not in use, the peripheral nozzle 44A stands by at the standby position. The standby section 45A is configured to store the thinner therein and to discharge the thinner from the inside thereof, and cleans the peripheral nozzle 44A in standby with the thinner stored therein at a certain timing.

As shown in FIG. 1 and FIG. 2, the reflecting member 34A is disposed between the cup 22A and the EBR standby section 45A. The reflecting member 34A is a standing-up plate with two main surfaces facing the X-axis direction in a plan view. Of the two main surfaces, the main surface on the right side (the side facing the cup 22A) forms a reflecting surface 35A. The reflecting surface 35A is located above the cup 22A, and faces a first illuminator 32, which is vertically movable, to be described later in a horizontal direction. The reflecting surface 35A is disposed so as to be inclined slightly downwards with respect to the horizontal direction. This allows light from the first illuminator 32 to be reflected toward the surface of the wafer W placed on the spin chuck 25A. As described above, the reflecting surface 35A is located on the opposite side to the side where the EBR standby section 45A is located. Therefore, even if the thinner splashes on the standby section 45A, adhesion of the thinner to the reflecting surface 35A is suppressed. Thus, since contamination of the reflecting surface 35A is suppressed, clarity of obtained image data is guaranteed.

As mentioned, the processing device 21B is configured in the same manner as the processing device 21A. Components of the processing device 21B that are identical to the components of the processing device 21A are assigned the same reference numerals as used in the processing device 21A. However, alphabets added to the numerals are different between the processing devices, and B is used as an alphabet indicating the processing device 21B. Further, the alphabets may sometimes be omitted for the same components of the processing devices 21A and 21B to generically refer to the components, such as the EBR mechanism 4, the processing device 21, the cup 22, the spin chuck 25, the reflecting member 43, the reflecting surface 35, and so forth.

On the front of and between the processing devices 21A and 21B, there is provided a standby section 48 for each nozzle 11 constituting the processing liquid supply mechanism 10. The standby section 48 is disposed on the front of the cups 22A and 22B. As indicated by a dashed line in FIG. 1, a detailed shape of this standby section 48 is omitted here. Briefly, however, the standby section 48 is configured as, for example, a table with a plurality of non-illustrated recesses opened upwards, and the nozzle 11 is accommodated in the corresponding recess to be in standby. Also, the standby section 48 is configured such that thinner can be supplied into the recesses and drained therefrom. With this configuration, the thinner is supplied onto an outer surface of the nozzle 11 in standby, thus cleaning the nozzle 11.

The processing liquid supply mechanism 10 is equipped with a plurality of nozzles 11 and a nozzle transfer mechanism 15 (e.g., nozzle transferer) as a moving body configured to transfer each nozzle 11 to above the wafer W disposed in each processing device 21, and serves to supply the processing liquid to the wafer W. The nozzle transfer mechanism 15 includes a guide 16 extending in the left-and-right direction on the front of the standby section 48, and an arm mechanism 17 (e.g., arm device) configured to locate the nozzle 11 at the discharge position above each wafer W placed on the spin chuck 25.

As shown in FIG. 1 and FIG. 2, the arm mechanism 17 includes a base 18 and an arm 19. The base 18 has an elevating mechanism 18a configured to be movable left and right along the guide 16, and an elevating member 18b connected to the elevating mechanism 18a and moved up and down. A base end of the elevating member 18b is disposed on the left side of the elevating mechanism 18a, and a leading end thereof extends rearwards. A base end of the arm 19 horizontally extending in, for example, a straight line shape is connected to the leading end of the elevating member 18b so as to be rotatable around a rotation axis 19a extending along the Z-axis. That is, the arm 19 is configured to pivot around the base end thereof along a horizontal plane.

Three nozzles 11 extending downwards are attached to a bottom portion of the leading end of the arm 19. Of these nozzles 11, one resist nozzle 11r configured to discharge the resist is disposed on the leading end side of the arm 19, and two thinner nozzles 11t configured to discharge the thinner are disposed closer to the base end side of the arm 19 than the resist nozzle 11r is. In this way, the resist nozzle 11r and the thinner nozzles 11t are arranged shifted from each other in an extension direction from the base end toward the leading end of the arm 19. The two thinner nozzles 11t are arranged in a direction intersecting the extension direction of the arm 19, specifically, orthogonal to the extension direction of the arm 19. Either one of the two thinner nozzles 11t is selected for use, and focus adjustment for the thinner nozzles 11t, which will be described later, is performed so that the focus is on these two thinner nozzles 11t.

The resist nozzle 11r is connected to a resist supply mechanism 12 equipped with a valve and a pump, and the resist supply mechanism 12 adjusts the amount of the resist supplied to the resist nozzle 11r. That is, the amount of the resist discharged from the resist nozzle 11r is adjusted by the resist supply mechanism 12. The thinner nozzle 11t is connected to a thinner supply mechanism 13 equipped with a valve and a pump, and the thinner supply mechanism 13 adjusts the amount of the resist supplied to the thinner nozzle 11t. That is, the amount of the thinner discharged from the thinner nozzle 11t is adjusted by the thinner supply mechanism 13. The resist nozzle 11r and thinner nozzle 11t as described above discharge the resist and the thinner downwards at the discharge position within the cup 22, which is located above the center of the wafer W held by the spin chuck 25.

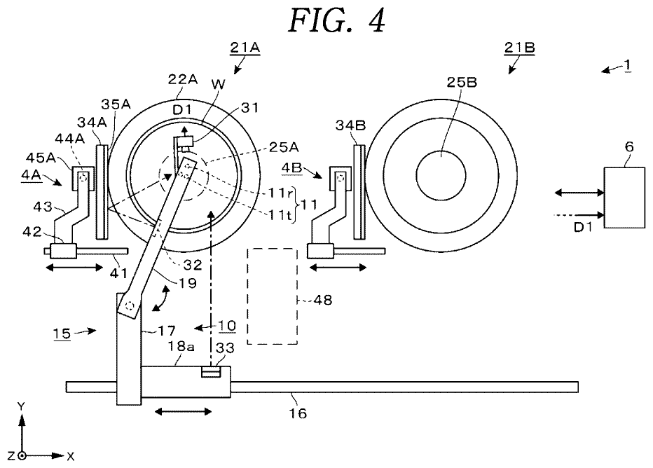

FIG. 1 and FIG. 4 show states in which the resist nozzle 11r and the thinner nozzle 11t are moved to the discharge position in the processing device 21A, respectively. At this time the arm 19 is extended rearwards to the right. Further, a positional relationship between the arm 19 and the processing device 21B when the resist nozzle 11r and the thinner nozzle 11t are moved to the discharge position in the processing device 21B is the same as the positional relationship between the arm 19 and the processing device 21A shown in FIG. 1 and FIG. 4.

The resist coating apparatus 1 includes the camera 31 configured to monitor the state of the nozzle 11, the first and second illuminators 32 and 33, and the reflecting member 34 described above. As illustrated in FIG. 1 and FIG. 2, the first illuminator 32 is provided under the base end side of the arm 19 so as to be located closer to the base of the arm 19 than the nozzle 11 is. The first illuminator 32 is configured to radiate light from a left side of the arm 19 (the left side in the direction from the base end toward the leading end of the arm 19), as indicated by an optical axis marked by a dashed dotted line. The first illuminator 32 is disposed substantially on a level with the reflecting surface 35A of the reflecting member 34 so that it may radiate the light rearwards to the left toward the reflecting surface 35A of the reflecting member 34 when each nozzle 11 is placed at the discharge position. The light radiated along the optical axis from the first illuminator 32 is reflected by the reflecting surface 35A and the surface of the wafer W, and illuminates each nozzle 11 from below and the left of the nozzle 11.

The second illuminator 33 is provided on the right front side of the elevating mechanism 18a, and is positioned higher than the cup 22. The second illuminator 33 is positioned so as to radiate light slightly downwards toward the rear as indicated by an optical axis marked by a dashed dotted line. This allows the second illuminator 33 to radiate the light from above the cup 22 toward the surface of the wafer W placed on the spin chuck 25. The second illuminator 33 is positioned in front of each nozzle 11 at the discharge position in a plan view, and the light radiated from the second illuminator 33 toward the surface of the wafer W is reflected by the wafer W to illuminate each nozzle 11 from below and the front side of the nozzle 11.

Now, the camera 31 will be described. The camera 31 is mounted to the arm 19 at a position and a posture allowing the resist nozzle 11r and the two thinner nozzles 11t to be included in an imaging range thereof. More specifically, the camera 31 is supported by a connecting member 31d protruding forward from the leading end of the arm 19, and is provided in an area extended from the arm 19 in a plan view. Imaging is performed from the leading end side of the arm 19 toward the base end side thereof.

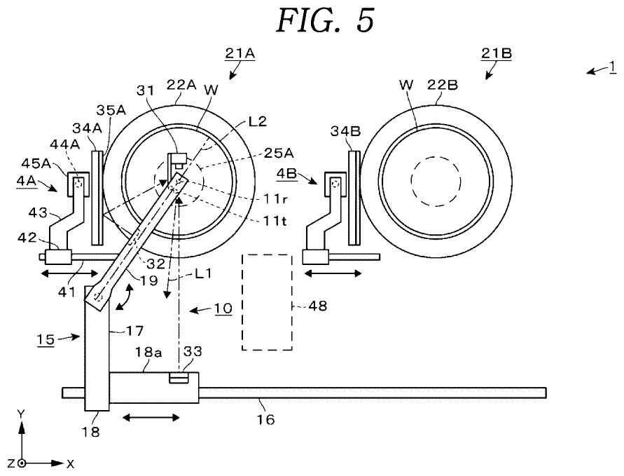

FIG. 5 is a plan view for describing an optical axis of the camera, etc. With respect to an optical axis L1 of the camera 31, the optical axes of the lights from the reflecting member 34A and the second illuminator 33 toward the nozzle 11 are located to the left and the right, respectively. In other words, when imaging each nozzle 11 and its vicinity with the camera 31, light is radiated to an imaging area from the left and the right, so that no shadow is casted on the nozzle 11. Also, in the plan view, the direction of the optical axis L1 of the camera 31 is misaligned with respect to the direction of a straight line L2 indicating the extension direction of the arm 19. That is, in the plan view, an extension line of the optical axis L1 and the straight line L2 intersect with each other. This configuration suppresses the components such as the elevating member 18b mounted to the base end of the arm 19 and the second illuminator 33 provided under the arm 19 from being included in the imaging range of the camera 31, thus improving accuracy of abnormality determination based on imaging data D1. Further, the optical axis L1 is inclined slightly downwards from the horizontal plane in order to include a space under the nozzle 11 in the imaging range.

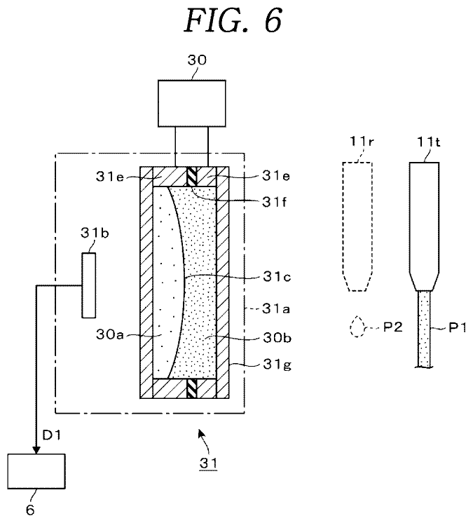

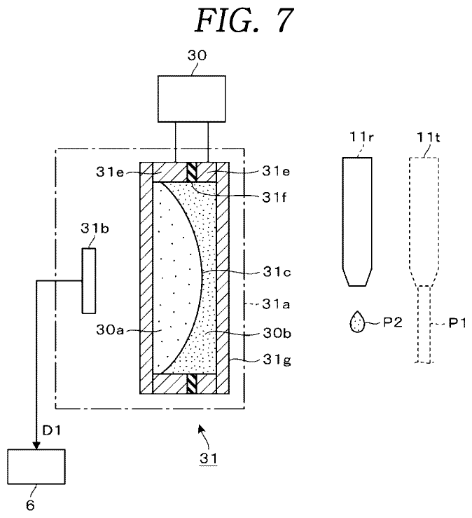

However, since the camera 31 is provided at the arm 19 as described above, a distance from the camera 31 to the resist nozzle 11r and a distance from the camera 31 to the thinner nozzle 11t are different. The camera 31 is configured to be capable of changing a focal length and focusing on each of the resist nozzle 11r and the thinner nozzle 11t. In the following description, reference will be made to FIG. 6 and FIG. 7 schematically showing the focus adjustment as well as FIG. 3. The camera 31 includes a housing 31a, and an image sensor 31b and a varifocal lens 31c accommodated in the housing 31a, and is connected to an external power source 30. The light passing through the varifocal lens 31c forms an image on the image sensor 31b. The image sensor 31b photoelectrically converts the received light to generate the imaging data D1, and transmits it to the controller 6 to be described later.

The varifocal lens 31c is an interface between two types of mutually separated liquids 30a and 30b enclosed in a lens kit 31g. When a voltage applied from the external power source 30 to electrodes 31e provided in the lens kit 31g changes, the shape of the interface between the liquids 30a and 30b changes as shown in FIG. 6 and FIG. 7, causing the focal length of the camera 31 to change as well. That is, the lens kit 31g is configured as a liquid lens. In the drawings, a reference numeral 31f is an insulating member that insulates the electrodes 31e from each other.

In FIG. 6 and FIG. 7, either one of the resist nozzle 11r and the thinner nozzle 11t that is in focus is indicated by a solid line, and the other that is not in focus is indicated by a dashed line. In the following description, the state in which the focus is on the thinner nozzle 11t as in FIG. 6 may sometimes be referred to as a first focus state, and the state in which the focus is on the resist nozzle 11r as in FIG. 7 may sometimes be referred to as a second focus state.

However, the imaging area of the camera 31 includes not only the nozzle 11 but also the vicinity of the nozzle 11. More specifically, the vicinity of the nozzle 11 includes an area below the nozzle 11. Thus, a liquid column P1 of the processing liquid formed by the nozzle 11 in focus and a liquid droplet P2 of the processing liquid dripping from the nozzle 11 can also be imaged in a focused state. The liquid column P1 and the liquid droplet P2 will be explained in further detail later.

The camera 31 configured as described above images the resist nozzle 11r and the thinner nozzle 11t in the imaging area repeatedly while focusing on them alternately, without moving the imaging range. That is, with the relative positions of the camera 31 and the resist nozzle 11r and the thinner nozzle 11t fixed, the first focus state and the second focus state are repeatedly switched to acquire the imaging data D1 of each nozzle 11, whereby the nozzles 11 are monitored. FIG. 4 and FIG. 6 illustrate states in which each nozzle 11 is being monitored when processing the wafer W by using the thinner nozzle 11t in a process S2 to be described later.

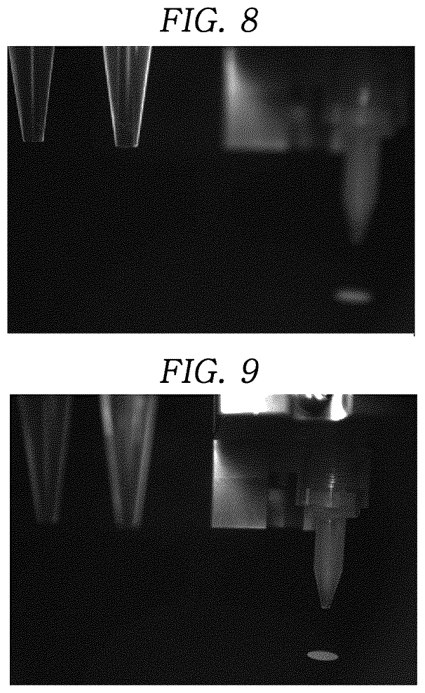

FIG. 8 is an example of imaging data in a state (first focus state of FIG. 6) where the camera takes an image while focusing on the thinner nozzle, and FIG. 9 is an example of imaging data in a state (second focus state of FIG. 7) where the camera takes an image while focusing on the resist nozzle. The switching between the first focus state and the second focus state may be performed in, for example, 100 ms or less. Here, the camera 31 is configured to have the liquid lens since the shape of the lens changes instantly (that is, the focus is adjusted) when a voltage is applied. More specifically, by using the liquid lens, it is possible to switch the focus in a very short time as shown in the example, as compared to a configuration in which the focus is adjusted by changing a positional relationship of respective members that constitute an optical system.

Hereinafter, the imaging data obtained by focusing on the resist nozzle 11r and the imaging data obtained by focusing on the thinner nozzle 11t may be simply referred to as the imaging data of the resist nozzle 11r and the imaging data of the thinner nozzle 11t. Also, the nozzle 11 as an imaging target in the imaging data refers to the resist nozzle 11r or the thinner nozzle 11t that is imaged relatively clearly through focus adjustment.

The resist coating apparatus 1 is equipped with the controller 6 which is a computer (see FIG. 1). The controller 6 includes a program storage for controlling an operation of each component of the resist coating apparatus 1, a memory, and an alarm output device. The program storage stores a program in which commands (process groups) are recorded to operate each component of the apparatus to form a resist film on the wafer W, as will be described below. The program storage is implemented by a recording medium such as a hard disk, a compact disk, a magnet optical disk, a memory card, or a DVD. The program causes the controller 6 to output control signals to the respective components of the resist coating apparatus 1 so that the aforementioned formation of the resist film may be carried out.

This program also enables switching of the used illuminators between the processing devices 21A and 21B, acquisition of the imaging data D1 by the camera 31, switching of the focus of the camera 31, and determination upon any abnormality in the resist nozzle 11r and the thinner nozzle 11t based on the imaging data D1. That is, this program serves as an imaging condition changing module that monitors the nozzle 11 and changes an imaging condition according to the monitoring condition (monitoring target). In addition, a countermeasure operation such as an alarm output performed in conjunction with the monitoring is also controlled by the program.

The monitoring of the nozzle 11 will be discussed in further detail. When one of the resist nozzle 11r and the thinner nozzle 11t is moved to the discharge position above the center of the wafer W to discharge the processing liquid (resist or thinner), the other is also moved to a position (referred to as a retreat position for the convenience of explanation) slightly deviated from the discharge position (see FIG. 1 and FIG. 4). The imaging data D1 is acquired with any one of the nozzles 11 positioned at the discharge position. At this time, by switching the focus, both the resist nozzle 11r and the thinner nozzle 11t are repeatedly imaged.

For the nozzle 11 that discharges the processing liquid at the discharge position, it is determined from the imaging data D1 whether or not the discharge state of the processing liquid is appropriate, and presence or absence of an abnormality is determined. When the processing liquid is discharged, the liquid column P1 of the processing liquid is formed under the nozzle 11, and the determination upon whether or not the discharge state of the processing liquid is appropriate includes determination upon whether or not the liquid column P1 is formed at an appropriate timing, whether or not the shape of the liquid column P1 is appropriate (whether or not its thickness is appropriate and whether or not it is deformed), and so forth.

For the nozzle 11 that is placed at the retreat position, presence or absence of an abnormality regarding a state other than the discharge state of the processing liquid is determined from the imaging data D1. As a specific example, falling (dripping) of the liquid droplet P2 from the nozzle 11 or the amount of the thinner adhering to the outer surface of the nozzle 11 after being used in the cleaning of the nozzle 11 are determined from the imaging data D1. The dripping liquid droplet P2 is the processing liquid, or the thinner used in the cleaning and attached to the nozzle 11. When managing a liquid surface position of the processing liquid in the nozzle 11 that is placed at the retreat position, it may be determined from the imaging data D1 whether the liquid surface position is within an allowable range.

The resist nozzle 11r and the thinner nozzle 11t are disposed close to each other by being provided on the same arm 19. While one nozzle 11 is located at the discharge position, the other nozzle 11 is located at the retreat position. This retreat position is also above the wafer W, just like the discharge position. Therefore, if the processing liquid or the thinner used in the cleaning falls from the nozzle 11 as described above, it may be supplied onto the wafer W, causing an abnormality. Also, if there is any abnormality in the discharge state of the processing liquid from the nozzle 11 at the discharge position, an appropriate amount of the processing liquid may not be supplied to the wafer W, or the processing liquid may splash on the wafer W and become a foreign matter, causing the abnormality. Since there is a risk that abnormalities in the respective nozzles 11 at the discharge position and the retreat position may cause a problem in the processing of the wafer W, the focus of the camera 31 is repeatedly switched at a high speed to repeatedly obtain the imaging data D1 of the respective nozzles 11 at the discharge position and the retreat position, and the abnormality determination is made based on each imaging data D1.

The determination on presence or absence of the abnormality is carried out as the program compares the acquired imaging data D1 with reference data of the nozzle 11, which is obtained when there is no abnormality and stored in the memory of the controller 6. If it is determined that there is the abnormality, an alarm is outputted from an alarm output device in the form of a predetermined sound or image.

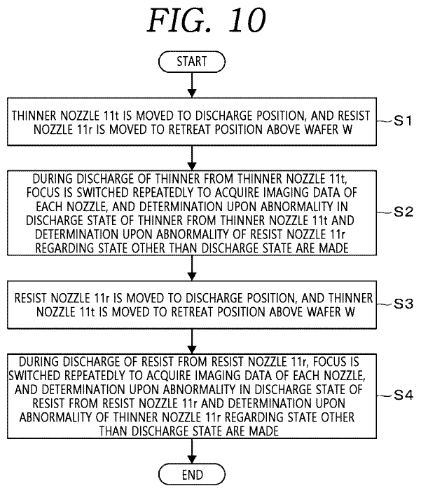

An operation of the resist coating apparatus will be described step by step with reference to a flowchart of FIG. 10. First, the wafer W is transferred to one of the processing devices 21A and 21B, for example, the processing device 21A, and is attracted to and held by the spin chuck 25. The thinner nozzle 11t and the resist nozzle 11r that are in standby in the standby section 48 are moved to the discharge position and the retreat position above the wafer W, respectively, and light is radiated from the first illuminator 32 and the second illuminator 33 of the processing device 21A to illuminate the thinner nozzle 11t and the resist nozzle 11r (process S1). Then, imaging by the camera 31 and repeated switching of the focus are performed to acquire the imaging data of the thinner nozzle 11t and the imaging data D1 of the resist nozzle 11r repeatedly.

In parallel with the acquisition of the imaging data D1 of the nozzle 11, the thinner is discharged from the thinner nozzle 11t, forming the liquid column P1. From the imaging data acquired for the thinner nozzle 11t, presence or absence of an abnormality in the discharge state of the thinner from the thinner nozzle 11t is determined. Also, from the imaging data D1 acquired for the resist nozzle 11r, presence or absence of an abnormality regarding a state other than the discharge state of the resist from the resist nozzle 11r (dripping of the liquid droplet P2, the amount of the thinner for cleaning adhering to the outer surface of the nozzle) is determined (process S2).

The discharge of the thinner from the thinner nozzle 11t is stopped, and the acquisition of the imaging data D1, the switching of the focus, and the determination of presence or absence of an anomality are temporarily stopped. The thinner supplied to the center of the wafer W is coated on the entire surface of the wafer W due to the rotation of the wafer W, so that pre-wetting is performed. Meanwhile, through the left and right movements and the pivoting movement of the arm 19, the resist nozzle 11r is moved to the discharge position above the wafer W after being subjected to the pre-wetting in the process S1, and the thinner nozzle 11t is moved to the retreat position (process S3).

The acquisition of the imaging data and the focus switching are resumed, and the imaging data of the thinner nozzle 11t and the imaging data D1 of the resist nozzle 11r are repeatedly acquired. In parallel with this acquisition of the imaging data of the nozzle 11, the resist is discharged from the resist nozzle 11r to form the liquid column P1. From the imaging data acquired for the resist nozzle 11r, presence or absence of an abnormality in the discharge state of the resist from the resist nozzle 11r is determined. Also, from the imaging data acquired for the thinner nozzle 11t, presence or absence of an abnormality regarding other than the discharge state of the thinner from the thinner nozzle 11t (dripping of the liquid droplet P2 and the amount of the thinner for cleaning adhering to the outer surface of the nozzle) is determined (process S4). Thus, the abnormality determination is performed in the same manner as in the process S2.

The discharge of the resist from the resist nozzle 11r is stopped, and the acquisition of the imaging data D1, the focus switching, the determination of the presence or absence of an abnormality, and the light radiation from the first illuminator 32 and the second illuminator 33 are stopped. The resist supplied to the center of the wafer W is coated on the entire surface of the wafer W due to the rotation of the wafer W, forming a resist film. The peripheral nozzle 44 is moved from the standby section 45A to the discharge position, the thinner is discharged to perform EBR, and the wafer W is then carried out from the processing device 21A.

While the wafer W is being processed in the processing device 21A as described above, another wafer W is transferred to the processing device 21B. Upon the completion of the discharge of the resist in the processing device 21A, the resist nozzle 11r and the thinner nozzle 11t are moved to the processing device 21B, where the wafer W is processed in the same sequence as in the processing in the processing device 21A, and during this processing, presence or absence of an abnormality in the nozzle 11 is determined. Afterwards, wafers W are repeatedly transferred to the processing devices 21A and 21B alternately to be subjected to the wafer processing and the abnormality determination as described above. If it is determined in the processes S2 and S4 of the processing devices 21A and 21B that there is an abnormality, an alarm is outputted. In addition to the output of the alarm, the processing of the wafer W may be stopped at the moment when the determination is made, and the resist nozzle 11r and the thinner nozzle 11t may be retuned back into the standby section 48, where cleaning of the respective nozzles 11 may be performed.

In each of the processes S2 and S4, a start time and an end time of the discharge of the processing liquid (the resist or the thinner) onto the wafer W is defined as t1 and t3, respectively, and a period from the time t1 to the time t3 is referred to as a processing liquid discharging period T1. When switching the focus as described above, a ratio of a focus time per unit time for each nozzle 11 may be varied during the processing liquid discharging period T1.

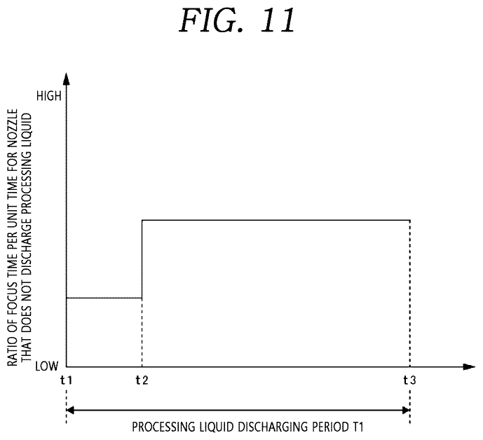

Reference is made to a graph of FIG. 11 showing a focus time ratio of the nozzle 11 that does not discharge the processing liquid (that is, the resist nozzle 11r in the process S2 and the thinner nozzle 11t in the process S4, for which the detection of the abnormality such as dripping is performed). In a period ranging from the start time t1 of the discharge of the processing liquid to a time point (denoted by time t2 in the graph) immediately thereafter, since the movement of the processing liquid toward the nozzle 11 is unstable as compared to that in a period after the time t2, there is a risk that the shape of the liquid column P1 formed under the nozzle 11 may also become unstable. Therefore, in a period from the time t1 to t2, the ratio of the focus time per unit time for the nozzle 11 that discharges the processing liquid and forms the liquid column P1 becomes relatively large, as compared to that in a period from the time t2 to t3. Thus, the ratio of the focus time per unit time for the nozzle 11 that does not discharge the processing liquid is set to be relatively small.

As a more specific example, when the focus switching is repeated in the process S2, the resist nozzle 11r is focused and kept in focus until time t11 elapses. Then, from the time t1 to t2, the thinner nozzle 11t is focused and kept in focus until the time t11+α elapses, and from the time t2 to t3, the thinner nozzle 11t is focused and kept in focus until the time t11 elapses. In this way, in the period from the time t1 to t2, the liquid column P1 of the thinner is imaged for a longer time than in the period from the time t2 to t3, thereby improving the detection accuracy for the abnormality in the liquid column P1.

In addition, as for the camera 31, the imaging data D1 is transmitted to the controller 6 at a regular interval. Therefore, if the ratio of the focus time per unit time for the nozzle 11 that does not discharge the processing liquid from the time t1 to t2 is small, this means that the frequency of the acquisition of the imaging data D1 of the nozzle 11 per unit time is low.

According to the resist coating apparatus as described above, the imaging by the camera 31 is performed under the imaging condition selected from a plurality of imaging conditions according to a monitoring condition of the nozzle 11. That is, depending on the monitoring condition of which one of the thinner nozzle 11t and the resist nozzle 11r is to be monitored, the imaging condition is selected such that either the first focus state for the thinner nozzle 11t or the second focus state for the resist nozzle 11r is set. Then, depending on the monitoring condition of which one of the monitoring of the nozzle 11 during the processing of the wafer W in the processing device 21A and the monitoring of the nozzle 11 during the processing of the wafer W in the processing device 21B is to be performed, the use of the first illuminator 32, the second illuminator 33, and the reflecting member 34A and the use of the first illuminator 32, the second illuminator 33, and the reflecting member 34B are switched. That is, the members to be used are selected as the imaging condition. Therefore, in the resist coating apparatus, the nozzles 11 can be monitored with high accuracy, so that the accuracy of the determination upon presence or absence of the abnormality can be improved.

In addition, each of the nozzle 11 at the discharge position and the nozzle 11 at the retreat position may cause the abnormality in the processing of the wafer W as stated above. Therefore, the monitoring these nozzles 11 and the detecting the abnormality are effective in suppressing a decrease in the yield of semiconductor products. In monitoring both the thinner nozzle 11t and the resist nozzle 11r in this way, using the common camera 31 through the focus switching enables the reduction in the number of cameras 31 that should be installed, which is desirable in terms of suppressing enlargement and cost-up of the apparatus. Further, although it is desirable that the camera 31 has the liquid lens for the reason of the focus switching speed as stated above, it may be also possible to adopt a configuration in which the camera 31 is not provided with the liquid lens.

In changing the imaging condition according to the monitoring condition, the imaging condition may be an illuminance by the first illuminator 32 and the second illuminator 33, or a threshold value for determining the abnormality in the imaging data D1. For example, assume that the apparatus is equipped with an additional illuminator besides the first illuminator 32 and the second illuminator 33, and there is a discrepancy in the illuminance between the processing devices 21A and 21B caused by the additional illuminator. In this case, in order to compensate for the discrepancy in the illuminance due to the additional illuminator, an illuminance of the light radiated from the first illuminator 32 and the second illuminator 33 in the processing device 21A toward the wafer W and an illuminance of the light radiated from the first illuminator 32 and the second illuminator 33 in the processing device 21B toward the wafer W are set to be different.

An example of changing the threshold value for the abnormality determination of the imaging data D1 will also be explained. The imaging data D1 acquired by the camera 31 is, for example, data with brightness information for each pixel. In determining whether the dripping of the liquid droplet P2 has occurred, the position of the nozzle 11 is specified in the imaging data D1. Then, when a group of pixels each exceeding a preset threshold value for brightness appears below the nozzle 11 and this group is formed of a number of pixels within a predetermined range, it is determined that the liquid droplet P2 has dripped off. This threshold value for brightness may be different in the processing of the wafer W in the processing device 21A and in the processing of the wafer W in the processing device 21B. For example, when imaging the nozzle 11 in the processing device 21A and when imaging the nozzle 11 in the processing device 21B, it is assumed that a structure of the apparatus captured in an area outside the nozzle 11 may be different. By setting the threshold value for brightness to be different in the abnormality determination based on the data obtained in the processing device 21A and in the abnormality determination based on the data obtained in the processing device 21B, the influence of the difference in the imaged structure on the abnormality determination may be suppressed.

In the present exemplary embodiment, in the period T1 during which the processing liquid is discharged from the nozzle 11, the focus switching is repeatedly performed, and the imaging data D1 is acquired whenever the focus is switched. However, the imaging data D1 may be acquired by repeatedly performing the focus switching only during a part of the period T1. In addition, the determination on presence or absence of the abnormality from the imaging data D1 may be performed at any timing.

Machine learning may be used to determine whether the nozzle 11 has any abnormality. For example, before processing the wafer W, a multiple number of imaging data acquired by the camera 31 for each of the nozzles 11r and 11t is stored in the memory of the controller 6 in advance. These imaging data include imaging data acquired when the dripping has occurred and imaging data acquired when there is no abnormality, and they are stored matched with information indicating that the dripping has occurred or that there is no abnormality, respectively. That is, learning about the dripping takes place.

Then, in the processes S2 and S4 during the above-described processing of the wafer W, when the imaging data D1 of the nozzle 11 that does not discharge the processing liquid is acquired, the imaging data that is most similar to the imaging data D1 acquired during this processing is selected from the multiple number of imaging data stored in the memory of the controller 6. Then, based on the information matched with the selected imaging data, there is made a determination that the dripping has occurred or that there is no abnormality. Through the determination using this machine learning, it is possible to accurately determine the presence or absence of the abnormality even when the amount of the light radiated from each illuminator to the nozzle 11 is relatively small or even when the component of the apparatus is captured in the area outside the nozzle 11 in the imaging data D1, for example. In addition, from the stored imaging data in which the dripping has occurred, predicted imaging data that is expected to include the dripping may be generated by a predetermined algorithm. In this case, when the actual imaging data D1 coincides with the predicted image data, there may be made a determination that the dripping has occurred.

The present disclosure can also be used to manage the liquid surface position of the processing liquid in the nozzle 11 as described above or to detect a defect of the nozzle 11 itself. In this case as well, machine learning may be used to identify a background object located behind the nozzle 11 in the imaging data in an area near the outline or the liquid surface of the nozzle 11 as something different from the nozzle 11 or its liquid surface. Examples of this background object include a pattern of a film formed on a surface of a substrate, a structure constituting the processing apparatus, and so forth. If this background object is located near the nozzle 11, it is difficult to determine and detect the nozzle shape and the liquid surface. By the above-described identification, the shape of the nozzle 11 and the liquid surface can be correctly recognized in the imaging data, which makes it easier to determine whether there is any nozzle damage such as contamination, scratches and deformation of the nozzle 11, and whether there is any abnormality such as dripping.

Furthermore, a nozzle damage including the leading end of the nozzle 11 may be determined or detected based on both of the state of the area corresponding to the nozzle 11 in the imaging data and the width of the liquid column of the processing liquid discharged from the nozzle 11. When imaging data is obtained by imaging the nozzle 11 from the side, a leading end surface and a side surface of the nozzle 11 may be in an overlapping area in the imaging data D1 depending on an imaging direction (optical axis L1), which makes it difficult to identify the location of the nozzle damage that should be detected in that area. In this case, if the width of the liquid column of the processing liquid discharged from the nozzle 11 is abnormal, for example, it may be possible to consider that the nozzle damage that has occurred at the leading end of the nozzle 11 including a discharge opening for the processing liquid is related to the abnormality in the width of the liquid column and make a determination that the nozzle damage is located at the leading end of the nozzle 11. That is, even when imaging the nozzle 11 from the side so it is difficult to identify the leading end of the nozzle 11, the presence or absence of the nozzle damage at the leading end of the nozzle 11 can still be determined.

For abnormalities other than the dripping, machine learning may be performed in the same manner as described above, and the presence or absence of the abnormality may be determined based on that machine learning when the wafer W is processed. By way of example, the presence or absence of the abnormality in the shape of the liquid column formed by the discharge of the processing liquid may also be determined by using machine learning. Due to scattering of the light radiated to the wafer W, it may become difficult to identify the shape of the liquid column from the imaging data D1 of the nozzle 11 obtained when the liquid column is formed. Even in such a case, through the use of the machine learning, any abnormality in the shape of the liquid column may be detected with high accuracy. Further, the determination on the presence or absence of the abnormality through this machine learning may be based on deep learning.

Machine learning is not limited to being used to determine the presence or absence of the abnormality, but may also be used to adjust the focus of the camera 31. When re-installing the camera 31 or nozzle 11 after removing it from the arm 19 for maintenance, the focus may shift due to a slight error in each component, so a user of the apparatus may manually adjust the focus. This adjustment is performed by changing the voltage that is applied to the electrode 31e of the lens kit 31g from the external power source 30 to adjust the shape of the varifocal lens 31c, while acquiring imaging data. After the focus adjustment, a maximum value minus a minimum value of the brightness of the imaging data of the nozzle 11 acquired before the focus adjustment (first time each component is re-installed), for example, is stored in the controller 6 while being matched with the voltage applied after the focus adjustment. If a number of such data of the maximum value minus the minimum value of the brightness matched with the application voltage are stored, the focus is automatically adjusted based on this data. Specifically, if imaging data of the nozzle 11 is acquired after each component is re-installed, the controller 6 calculates the maximum value minus the minimum value of the brightness of that imaging data, selects a value that is closest to the calculated value from the stored data, and corrects the application voltage so that it becomes an application voltage of that data.

The presence of the dripping liquid droplet P2 is determined by whether the brightness of the group of pixels exceeds the preset threshold value, and this threshold value will be further explained. Prior to the processing of the wafer W, imaging data of the nozzle 11 is acquired in advance, and average brightness of each pixel is calculated. This average brightness value and the aforementioned threshold value are stored matched with each other. For the setting of the threshold value for the average value, a relatively low value is set within a range where it is possible to make a determination regarding the liquid droplet. Then, by radiating light or disposing a structure around the nozzle 11, the average brightness value of the imaging data is changed. A relatively low threshold value is set for the average brightness value thus changed, and they are stored while being matched with each other. In this way, the data in which the average brightness value are matched with the threshold value are repeatedly acquired. When processing the wafer W, the average brightness value is obtained from the obtained imaging data, and among the stored data, the threshold value of the data that is closest to the average brightness value is used to determine whether or not dripping has occurred.

Furthermore, presence or absence of the liquid column P1 is determined in the same way as the presence or absence of the dripping liquid droplet P2. Thus, the same as in the case of the dripping liquid droplet P2, a threshold value needs to be set to a relatively low value based on the imaging data actually acquired. If another structure is captured around the nozzle 11 in the imaging data, the average brightness value may become relatively high, and when the threshold value is low, there is a risk that the structure may be mistakenly detected as the liquid droplet P2 or the liquid column P1. If, however, the average brightness value is low, that is, if the capture of another structure is suppressed, such mistaken detection is suppressed. Thus, a relatively low threshold value is set based on the data stored in advance as described above. This increases detection sensitivity for the dripping liquid droplets P2 and the liquid column P1.

Now, modification examples of the illuminator and the reflecting member will be explained. FIG. 12 is a plan view illustrating a first modification example. In the first modification example, reflecting members 34A and 34B may be disposed on the right of each cup 22, a first illuminator 32 may be disposed on the right side of the arm 19, and a second illuminator 33 may be disposed on the left side of the elevating mechanism 18a. In this case, the first illuminator 32 and the second illuminator 33 radiate light to the nozzle 11 from the opposite sides in the left-and-right direction from the present exemplary embodiment.

In the first modification example and the present exemplary embodiment, the first illuminator 32 is provided at the arm 19, and the second illuminator 33 is provided at the elevating mechanism 18a. However, this is not an essential requirement. For example, the first illuminator 32 may be disposed outside and above each cup 22, the same as the second illuminator 33. As another example, the second illuminator 33 may be provided at the arm 19, and two sets of reflecting members 34 may be provided for each processing device 21. In either case, it is desirable that the first illuminator 32 and the second illuminator 33 are disposed so as to illuminate the nozzle 11 from both the left and right sides.

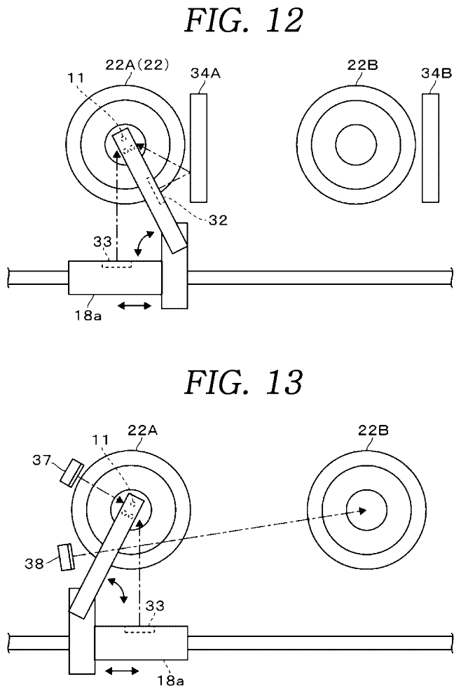

In a second modification example as shown in FIG. 13, the first illuminator 32 is not provided at the arm 19, and the reflecting member 34 is not provided. In this modification example, a fourth illuminator 37 and a fifth illuminator 38 are disposed to correspond to each cup 22. Specifically, the fourth illuminator 37 and the fifth illuminator 38 are disposed on the left of the cup 22A so as to radiate light to the nozzle 11 above the wafer W in each cup 22 from the left. The fourth illuminator 37 is configured to illuminate the nozzle 11 from the side when the nozzle 11 is discharging the processing liquid in the cup 22A. The fifth illuminator 38 is configured to illuminate the nozzle 11 from slightly behind when the nozzle 11 is discharging the processing liquid in the cup 22B, and is disposed such that an optical axis thereof does not pass through the centers of the cups 22A and 22B in a plan view.

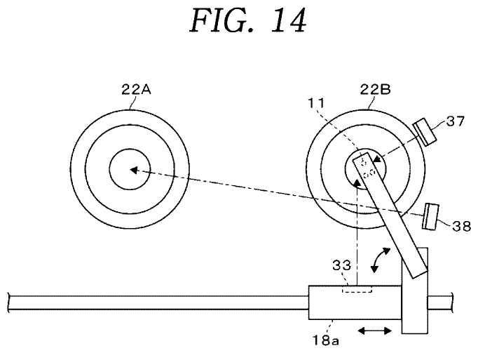

In a third modification example as shown in FIG. 14, the fourth and fifth illuminators 37 and 38 in the second modification example are disposed reversely in the left-and-right direction. That is, the fourth and fifth illuminators 37 and 38 are disposed on the right of the cup 22B so as to radiate light to the nozzle 11 above each cup 22 from the right. As described above, the configuration and the layout of the illuminators in the present disclosure may be set as required.

The number of the processing devices 21 is not limited to two, and more than two processing devices may be provided. By way of example, a processing device 21C may be provided in addition to the processing devices 21A and 21B, so the three processing devices 21A to 21C may be provided in total. These processing devices 21A to 21C may be arranged in a straight line shape in the left-and-right direction, and the processing liquid supply mechanism 10 may be shared by the three processing devices 21. In such a configuration with the processing device 21C as well, the layout of the above-described examples may be applied to the layout of the reflecting member 34 and the illuminators. That is, in case of providing the reflecting member 34 and the first illuminator 32 for each processing device 21, the cup 22, the reflecting member 34, and the first illuminator 32 may be provided in the processing device 21C in the same layout as the cup 22, the reflecting member 34, and the first illuminator 32 in the processing device 21A and 21B. Although the illuminator is illustrated as being shared by the processing devices 21 in the shown example, it needs to be shared by the processing devices 21A to 21C.

The liquid processing apparatus to which the technique of the present disclosure is applied is not limited to the resist coating apparatus. For example, instead of the resist, a chemical liquid for forming an anti-reflection film or a chemical liquid for forming an insulating film may be discharged from the nozzle 11r. Further, the technique of the present disclosure may also be applicated to a liquid processing apparatus equipped with, on the arm 19, a nozzle configured to supply a developing liquid to the exposed resist film and a nozzle configured to supply a cleaning liquid such as pure water to clean the surface of the wafer W after the supply of the developing liquid.

Furthermore, in the respective exemplary embodiments, the substrate as a processing target is not limited to the wafer, and may be, by way of example, a substrate for manufacturing a flat panel display or a mask substrate for manufacturing a mask for exposure. Thus, it may be possible to process a rectangular substrate.

Here, it should be noted that the above-described exemplary embodiments are illustrative in all aspects and are not anyway limiting. The above-described exemplary embodiments may be omitted, replaced and modified in various ways without departing from the scope and the spirit of claims.

According to the exemplary embodiment, it is possible to monitor the state of the plurality of nozzles appropriately for the situation.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A liquid processing apparatus, comprising:
multiple stages on each of which a substrate is to be placed;
multiple nozzles shared by the multiple stages, and each nozzle being configured to supply a processing liquid to the substrate;
a camera shared by the multiple nozzles, the camera being configured to monitor states of the multiple nozzles; and
an imaging condition changing program module for causing circuitry to change an imaging condition of the camera according to a monitoring target.

2. The liquid processing apparatus of claim 1, further comprising:
a moving body provided with the multiple nozzles, the moving body moving with respect to each stage to supply the processing liquid to the substrate on each stage;
an illuminator provided at the moving body, the illuminator being for radiating light in a direction different from a direction toward each nozzle; and
a reflector fixed in position relative to each stage, the reflector being for reflecting the light radiated from the illuminator toward each nozzle.

3. The liquid processing apparatus of claim 2,
wherein the reflector reflects the light from the illuminator toward the substrate on each stage, and the light reflected from the substrate is radiated to each nozzle.

4. The liquid processing apparatus of claim 2,
wherein the reflector is provided for each stage.

5. The liquid processing apparatus of claim 1,
wherein the camera comprises a liquid lens, the camera having an imaging range including the multiple nozzles, and
the imaging condition changing program module causes the circuitry to change a focus of the camera according to at least one of the multiple nozzles designated as the monitoring target to monitor the states of the multiple nozzles.

6. The liquid processing apparatus of claim 5,
wherein by changing the focus, monitoring of a discharge state of the processing liquid from a first nozzle of the multiple nozzles and monitoring of a state of a second nozzle of the multiple nozzles are performed alternately, and
the state of the second nozzle is not a discharging state.

7. The liquid processing apparatus of claim 1, further comprising:
an arm provided with the multiple nozzles, the arm being configured to be moved with respect to each stage to supply the processing liquid to the substrate on each stage,
wherein the camera is provided at the arm such that an optical axis thereof is in a direction different from an extension direction of the arm in a plan view.

8. A monitoring method, comprising:
placing a substrate on each of multiple stages;
supplying a processing liquid to each substrate by multiple nozzles;
monitoring states of the multiple nozzles by imaging each nozzle with a camera; and
changing an imaging condition of the camera according to a monitoring target.

9. The monitoring method of claim 8,
wherein the camera comprises a liquid lens,
the monitoring states of the multiple nozzles includes:
performing the imaging such that the multiple nozzles are included in an imaging range of the camera, and
changing a focus according to at least one of the multiple nozzles as the monitoring target.

10. The monitoring method of claim 8, wherein the multiple nozzles are disposed on a moving body, and
the supplying the processing liquid includes moving the moving body to supply the processing liquid to the multiple stages.

11. The monitoring method of claim 10, further comprising:
radiating light towards the multiple nozzles using an illuminator provided on the moving body and reflecting the light using a reflector,
wherein the reflector is fixed in position relative to each stage.

12. The monitoring method of claim 11, wherein the reflector reflects the light from the illuminator toward the substrate on each stage, and the light reflected from the substrate is radiated to each nozzle.

13. The monitoring method of claim 8, wherein the camera comprises a liquid lens, the camera having the imaging range including the multiple nozzles, and
the method further comprising changing the focus of the camera according to at least one of the multiple nozzles designated as the monitoring target to monitor the states of the multiple nozzles.

14. The monitoring method of claim 13, wherein by changing the focus of the camera, monitoring of a discharge state of the processing liquid from a first nozzle of the multiple nozzles and monitoring of a state of a second nozzle of the multiple nozzles, are alternately performed, and
the state of the second nozzle is not a discharging state.

15. The monitoring method of claim 13, wherein the liquid lens of the camera is a varifocal lens, the varifocal lens including two types of mutually separated liquids enclosed in a lens kit, and
changing the focus of the camera is performed by applying a voltage from an external power source to electrodes of the lens kit.

16. The monitoring method of claim 8, further comprising:
transferring, by a nozzle transferer, the multiple nozzles from a first stage among the multiple stages to a second stage among the multiple stages,
wherein the nozzle transferer includes:
a guide extending in a left-right direction; and
an arm device.

17. The monitoring method of claim 16, further comprising:
locating, by the arm device, the multiple nozzles at a discharge position.

18. The monitoring method of claim 17, wherein the supplying the processing liquid to each substrate includes rotating a spin chuck of one stage of the multiple stages to hold the substrate to the one stage.

19. The monitoring method of claim 16, wherein the multiple nozzles includes:
a resist nozzle; and
a thinner nozzle, and
the method further comprising:
discharging, by the resist nozzle, resist onto the substrate; and
discharging, by the thinner nozzle, a thinner onto the substrate.

20. The monitoring method of claim 19, wherein the thinner nozzle is shifted from the resist nozzle in an extension direction from a base end of the arm device towards a leading end of an arm of the arm device.
